(19) United States
(12) Patent Application Publication
(10) Pub. No.: US 2022/0148664 A1
(43) Pub. Date: May 12, 2022

(54) CONTROLLER AND METHOD OF OPERATING THE SAME

(71) Applicant: SK hynix Inc., Icheon (KR)

(72) Inventor: Chan Hyeok CHO, Icheon (KR)

(21) Appl. No.: 17/327,372

(22) Filed: May 21, 2021

(30) Foreign Application Priority Data
Nov. 11, 2020 (KR) 10-2020-0150226

(51) Int. Cl. G11C 16/34; G11C 16/10; G11C 16/26; G11C 16/30; G11C 29/02

(52) U.S. Cl. CPC G11C 16/3404; G11C 16/102; G11C 29/02; G11C 16/30; G11C 16/26

(57) ABSTRACT

A controller controls an operation of a semiconductor memory device including a reference storage area and a normal storage area. The controller includes a power supply sensor, a command generator, and a refresh count manager. The power supply sensor generates a power-on signal indicating that a memory system including the controller is powered-on. The command generator generates a read command for reading reference data stored in the reference storage area in response to the power-on signal and transfer the read command to the semiconductor memory device. The refresh count manager analyzes the read reference data received from the semiconductor memory device and determines whether a threshold voltage distribution of memory cells included in the reference storage area is changed. The command generator controls the semiconductor memory device to perform a refresh operation on the reference data stored based on a result of the determination of the refresh count manager.

### CROSS-REFERENCE TO RELATED APPLICATION

The present application claims priority under 35 U.S.C. § 119(a) to Korean patent application number 10-2020-0150226, filed on Nov. 11, 2020, in the Korean Intellectual Property Office, the entire disclosure of which is incorporated herein by reference.

### BACKGROUND

### 1. Technical Field

The present disclosure relates to an electronic device, and more particularly, to a controller and a method of operating the same.

### 2. Related Art

A semiconductor memory device may be formed in a two-dimensional structure in which strings are horizontally arranged on a semiconductor substrate, or in a three-dimensional structure in which the strings are vertically stacked on the semiconductor substrate. A three-dimensional semiconductor memory device is a semiconductor memory device designed in order to resolve a limit of integration degree of a two-dimensional semiconductor memory device, and may include a plurality of memory cells that are vertically stacked on a semiconductor substrate.

A controller may control an operation of the semiconductor memory device.

### SUMMARY

An embodiment of the present disclosure provides a controller capable of analyzing a change of a threshold voltage distribution of a memory cell included in a semiconductor memory device, and a method of operating the controller.

According to an embodiment of the present disclosure, a controller controls an operation of a semiconductor memory device including a reference storage area and a normal storage area. The controller includes a power supply sensor, a command generator, and a refresh count manager. The power supply sensor generates a power-on signal indicating that a memory system including the controller is powered-on. The command generator generates a read command for reading reference data stored in the reference storage area in response to the power-on signal and transfer the read command to the semiconductor memory device. The refresh count manager analyzes the read reference data received from the semiconductor memory device and determines whether a threshold voltage distribution of memory cells included in the reference storage area is changed. The command generator controls the semiconductor memory device to perform a refresh operation on the reference data stored in the reference storage area based on a result of the determination of the refresh count manager.

According to another embodiment of the present disclosure, a method of operating a controller that controls an operation of a semiconductor memory device including a reference storage area and a normal storage area includes sensing a turn-on state of a memory system including the controller, reading reference data stored in the reference storage area, determining whether a threshold voltage distribution of memory cells included in the reference storage area is changed, based on the read reference data, and performing a refresh operation on the reference data stored in the reference storage area in response to a determination that the threshold voltage distribution is changed by a degree equal to or greater than a predetermined threshold value.

### BRIEF DESCRIPTION OF THE DRAWINGS

FIG. 1 is a block diagram illustrating a memory system according to an embodiment of the present disclosure.

FIG. 2 is a block diagram illustrating a semiconductor memory device of FIG. 1.

FIG. 3 is a diagram illustrating a memory cell array of FIG. 2 according to an embodiment of the present disclosure.

FIG. 4 is a circuit diagram illustrating a memory block of FIG. 3 according to an embodiment of the present disclosure.

FIG. 5 is a circuit diagram illustrating a memory block of FIG. 3 according to another embodiment of the present disclosure.

FIG. 6 is a circuit diagram illustrating a memory block of FIG. 2 according to an embodiment of the present disclosure.

FIG. 7 is a block diagram illustrating a controller according to an embodiment of the present disclosure.

FIG. 8 is a flowchart illustrating a method of operating a controller according to an embodiment of the present disclosure.

FIG. 9 is a diagram illustrating steps S110 to S130 of FIG. 8.

FIG. 10 is a diagram illustrating steps S150 to S170 of FIG. 8.

FIGS. 11A to 11D are diagrams illustrating step S130 of FIG. 8 according to an embodiment of the present disclosure.

FIGS. 12A to 12D are diagrams illustrating step S130 of FIG. 8 according to another embodiment of the present disclosure.

FIGS. 13A to 13C are diagrams illustrating step S130 of FIG. 8 according to still another embodiment of the present disclosure.

FIGS. 14A to 14D are diagrams illustrating step S130 of FIG. 8 according to still another embodiment of the present disclosure.

FIG. 15 is a diagram illustrating a bad block-refresh count association table according to an embodiment of the present disclosure.

FIG. 16 is a block diagram illustrating an example of a controller shown in FIG. 1.

FIG. 17 is a block diagram illustrating an application example of the memory system of FIG. 1.

FIG. 18 is a block diagram illustrating a computing system including the memory system described with reference to FIG. 17.

### DETAILED DESCRIPTION

Specific structural or functional descriptions of embodiments according to the concept which are disclosed in the present specification or application are illustrated only to describe the embodiments according to the concept of the present disclosure. The embodiments according to the concept of the present disclosure may be carried out in various forms and are not limited to the embodiments described in the present specification or application.

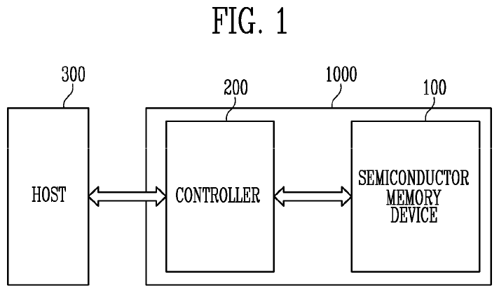

FIG. 1 is a block diagram illustrating a memory system 1000 according to an embodiment of the present disclosure.

Referring to FIG. 1, the memory system 1000 includes a semiconductor memory device 100 and a controller 200. In addition, the memory system 1000 communicates with a host 300. The controller 200 controls an overall operation of the semiconductor memory device 100. In addition, the controller 200 controls the operation of the semiconductor memory device 100 based on a command received from the host 300.

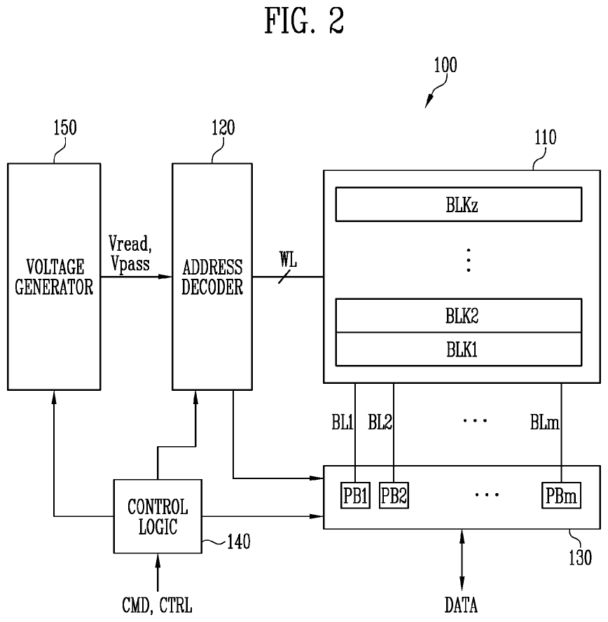

FIG. 2 is a block diagram illustrating the semiconductor memory device 100 of FIG. 1.

Referring to FIG. 2, the semiconductor memory device 100 includes a memory cell array 110, an address decoder 120, a read and write circuit 130, a control logic 140, and a voltage generator 150.

The memory cell array 110 includes a plurality of memory blocks BLK1 to BLKz, z being a positive integer. The plurality of memory blocks BLK1 to BLKz are connected to the address decoder 120 through word lines WL. The plurality of memory blocks BLK1 to BLKz are connected to the read and write circuit 130 through bit lines BL1 to BLm, m being a positive integer. Each of the plurality of memory blocks BLK1 to BLKz includes a plurality of memory cells. As an embodiment, the plurality of memory cells are non-volatile memory cells having a vertical channel structure.

In an embodiment, the memory cell array 110 may be configured as a memory cell array of a two-dimensional structure. In another embodiment, the memory cell array 110 may be configured as a memory cell array of a three-dimensional structure. Meanwhile, each of the plurality of memory cells included in the memory cell array 110 may store at least one bit of data. In an embodiment, each of the plurality of memory cells included in the memory cell array 110 may be a single-level cell (SLC) storing one bit of data. In another embodiment, each of the plurality of memory cells included in the memory cell array 110 may be a multi-level cell (MLC) storing two bits of data. In still another embodiment, each of the plurality of memory cells included in the memory cell array 110 may be a triple-level cell storing three bits of data. In still another embodiment, each of the plurality of memory cells included in the memory cell array 110 may be a quad-level cell storing four bits of data. According to other embodiments, the memory cell array 110 may include a plurality of memory cells each storing five or more bits of data.

The address decoder 120, the read and write circuit 130, the control logic 140, and the voltage generator 150 operate as a peripheral circuit that drives the memory cell array 110. The address decoder 120 is connected to the memory cell array 110 through the word lines WL. The address decoder 120 is configured to operate under the control of the control logic 140. The address decoder 120 receives an address through an input/output buffer (not shown) inside the semiconductor memory device 100.

The address decoder 120 is configured to decode a block address among received addresses. The address decoder 120 selects at least one memory block according to the decoded block address. In addition, during a read operation, the address decoder 120 applies a read voltage Vread to a selected word line of the selected memory block and applies a pass voltage Vpass to the remaining unselected word lines of the selected memory block. In addition, during a program verify operation, the address decoder 120 applies a verify voltage to the selected word line of the selected memory block and applies the pass voltage Vpass to the remaining unselected word lines of the selected memory block.

The address decoder 120 is configured to decode a column address among the received addresses. The address decoder 120 transmits the decoded column address to the read and write circuit 130.

A read operation and a program operation of the semiconductor memory device 100 are performed in a page unit.

The received addresses include a block address, a row address, and a column address. The address decoder 120 selects one memory block and one word line according to the block address and the row address. The column address is decoded by the address decoder 120 and is provided to the read and write circuit 130.

The address decoder 120 may include a block decoder, a row decoder, a column decoder, an address buffer, and the like.

The read and write circuit 130 includes a plurality of page buffers PB1 to PBm. The read and write circuit 130 may operate as a “read circuit” during a read operation of the memory cell array 110 and may operate as a “write circuit” during a write operation of the memory cell array 110. The plurality of page buffers PB1 to PBm are connected to the memory cell array 110 through the bit lines BL1 to BLm. During the read operation and the program verify operation, in order to sense a threshold voltage of memory cells, the plurality of page buffers PB1 to PBm sense a change of an amount of a current flowing through the memory cells according to program states of the memory cells through sensing nodes while continuously supplying a sensing current to bit lines connected to the memory cells, and latches the sensed change as sensed data. The read and write circuit 130 operates in response to page buffer control signals output from the control logic 140.

During the read operation, the read and write circuit 130 senses data stored in the memory cells, temporarily stores read data, and outputs data DATA to the input/output buffer (not shown) of the semiconductor memory device 100. As an embodiment, the read and write circuit 130 may include a column selection circuit, and the like, in addition to the page buffers PB1 to PBm (or page registers).

The control logic 140 is connected to the address decoder 120, the read and write circuit 130, and the voltage generator 150. The control logic 140 receives a command CMD and a control signal CTRL through the input/output buffer (not shown) of the semiconductor memory device 100 from the controller 200 of FIG. 1. The control logic 140 is configured to control overall operations of the semiconductor memory device 100 in response to the command CMD and the control signal CTRL. In addition, the control logic 140 outputs a control signal for adjusting a pre-charge potential level of sensing nodes of the plurality of page buffers PB1 to PBm. The control logic 140 may control the read and write circuit 130 to perform the read operation and the write operation of the memory cell array 110.

The voltage generator 150 generates the read voltage Vread and the pass voltage Vpass used in the read operation in response to a control signal output from the control logic 140. In order to generate a plurality of voltages having various voltage levels, the voltage generator 150 may include a plurality of pumping capacitors that receive an internal power voltage, and generate the plurality of voltages by selectively activating the plurality of pumping capacitors under the control of the control logic 140. The voltage generator 150 may include a charge pump, and the charge pump may include the plurality of pumping capacitors described above. A specific configuration of the charge pump included in the voltage generator 150 may be variously designed as necessary.

The address decoder 120, the read and write circuit 130, and the voltage generator 150 may function as a “peripheral circuit” that performs a read operation, a write operation, and an erase operation on the memory cell array 110. The peripheral circuit performs the read operation, the write operation, and the erase operation on the memory cell array 110 under the control of the control logic 140.

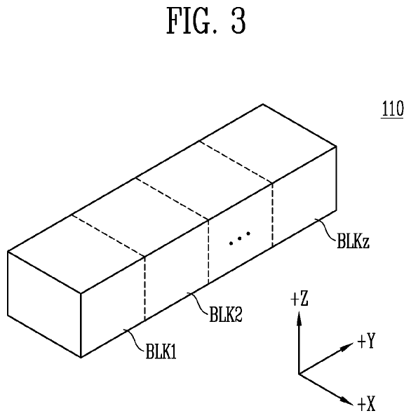

FIG. 3 is a diagram illustrating the memory cell array 110 of FIG. 2 according to an embodiment.

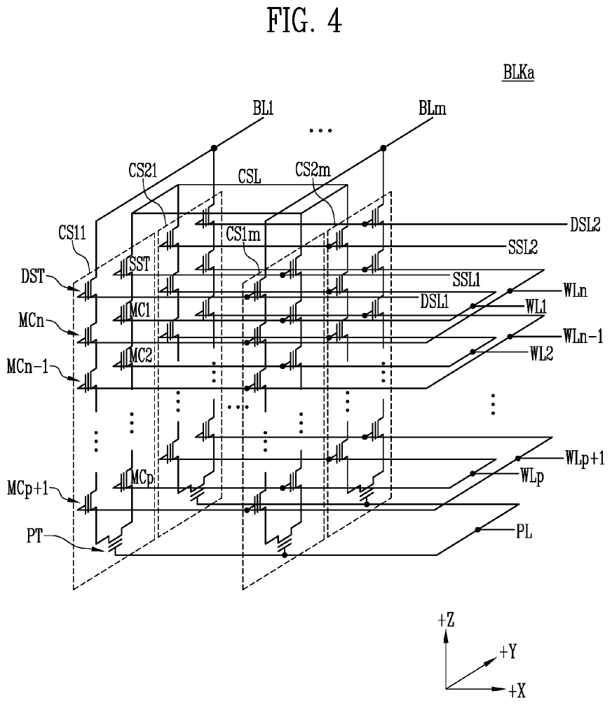

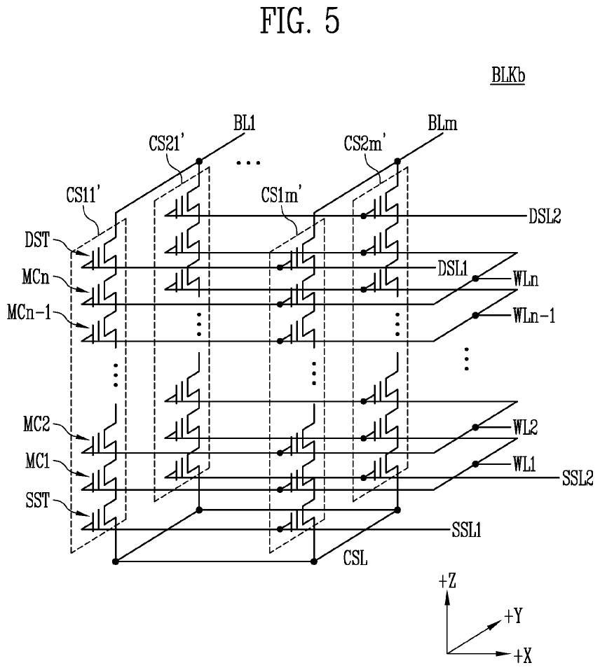

Referring to FIG. 3, the memory cell array 110 includes a plurality of memory blocks BLK1 to BLKz. Each memory block may have a three-dimensional structure. Each memory block includes a plurality of memory cells stacked on a substrate. Such plurality of memory cells are arranged along a +X direction, a +Y direction, and a +Z direction. A structure of each memory block is described in more detail with reference to FIGS. 4 and 5.

FIG. 4 is a circuit diagram illustrating a memory block BLKa according to an embodiment. The memory block BLKa may correspond to any one of the memory blocks BLK1 to BLKz of FIG. 3.

Referring to FIG. 4, the memory block BLKa includes a plurality of cell strings CS11 to CS1m and CS21 to CS2m. As an embodiment, each of the plurality of cell strings CS11 to CS1m and CS21 to CS2m may be formed in a ‘U’ shape. In the memory block BLKa, m cell strings are arranged in a row direction (that is, the +X direction). In FIG. 4, two cell strings are arranged in a column direction (that is, the +Y direction). However, this is for convenience of description and it may be understood that three or more cell strings may be arranged in the column direction.

Each of the plurality of cell strings CS11 to CS1m and CS21 to CS2m includes at least one source select transistor SST, first to n-th memory cells MC1 to MCn, a pipe transistor PT, and at least one drain select transistor DST.

Each of the select transistors SST and DST and the memory cells MC1 to MCn may have a similar structure. As an embodiment, each of the select transistors SST and DST and the memory cells MC1 to MCn may include a channel layer, a tunneling insulating film, a charge storage film, and a blocking insulating film. As an embodiment, a pillar for providing the channel layer may be provided in each cell string. As an embodiment, a pillar for providing at least one of the channel layer, the tunneling insulating film, the charge storage film, and the blocking insulating film may be provided in each cell string.

The source select transistor SST of each cell string is connected between a common source line CSL and the memory cells MC1 to MCp.

As an embodiment, the source select transistors of the cell strings, e.g., CS11 to CS1m, arranged in the same row are connected to a source select line, e.g., SSL1, extending in the row direction, and the source select transistors of the cell strings, e.g., CS11 and CS21, arranged in different rows are respectively connected to different source select lines, e.g., SSL1 and SSL2. That is, in FIG. 4, the source select transistors of the cell strings CS11 to CS1m of a first row are connected to a first source select line SSL1. The source select transistors of the cell strings CS21 to CS2m of a second row are connected to a second source select line SSL2.

As another embodiment, the source select transistors of the cell strings CS11 to CS1m and CS21 to CS2m may be commonly connected to one source select line.

The first to n-th memory cells MC1 to MCn of each cell string are connected between the source select transistor SST and the drain select transistor DST.

The first to n-th memory cells MC1 to MCn may be divided into first to p-th memory cells MC1 to MCp and (p+1)-th to n-th memory cells MCp+1 to MCn. The first to p-th memory cells MC1 to MCp are sequentially arranged in a direction opposite to the +Z direction, and are connected in series between the source select transistor SST and the pipe transistor PT. The (p+1)-th to n-th memory cells MCp+1 to MCn are sequentially arranged in the +Z direction, and are connected in series between the pipe transistor PT and the drain select transistor DST. The first to p-th memory cells MC1 to MCp and the (p+1)-th to n-th memory cells MCp+1 to MCn are connected to each other through the pipe transistor PT. Gates of the first to n-th memory cells MC1 to MCn of each cell string are connected to first to n-th word lines WL1 to WLn, respectively.

A gate of the pipe transistor PT of each cell string is connected to a pipeline PL.

The drain select transistor DST of each cell string is connected between a corresponding bit line and the memory cells MCp+1 to MCn. The cell strings arranged in the row direction are connected to the drain select line extending in the row direction. The drain select transistors of the cell strings CS11 to CS1m of the first row are connected to a first drain select line DSL1. The drain select transistors of the cell strings CS21 to CS2m of the second row are connected to a second drain select line DSL2.

The cell strings arranged in the column direction are connected to a corresponding bit line extending in the column direction. In FIG. 4, the cell strings CS11 and CS21 of a first column are connected to a first bit line BL1. The cell strings CS1m and CS2m of an m-th column are connected to an m-th bit line BLm.

The memory cells connected to the same word line in the cell strings arranged in the row direction configure one page. For example, the memory cells connected to the first word line WL1 among the cell strings CS11 to CS1m of the first row configure one page. The memory cells connected to the first word line WL1 among the cell strings CS21 to CS2m of the second row configure another page. The cell strings arranged in one row direction may be selected by selecting any one of the drain select lines DSL1 and DSL2. One page of the selected cell strings may be selected by selecting one of the word lines WL1 to WLn.

As another embodiment, even bit lines and odd bit lines may be provided instead of the first to m-th bit lines BL1 to BLm. In addition, even-numbered cell strings among the cell strings CS11 to CS1m or CS21 to SC2m arranged in the row direction may be connected to the even bit lines, and odd-numbered cell strings among the cell strings CS11 to CS1m or CS21 to CS2m arranged in the row direction may be connected to the odd bit lines, respectively.

As an embodiment, at least one of the first to n-th memory cells MC1 to MCn may be used as a dummy memory cell. In another embodiment, at least one dummy memory cell is provided to reduce an electric field between the source select transistor SST and the memory cells MC1 to MCp. Alternatively, at least one dummy memory cell is provided to reduce an electric field between the drain select transistor DST and the memory cells MCp+1 to MCn. As more dummy memory cells are provided in addition to the memory cells MC1 to MCn, reliability of an operation for the memory block BLKa is improved, but the size of the memory block BLKa increases. As less memory cells are provided, the size of the memory block BLKa may be reduced, but the reliability of the operation for the memory block BLKa may be reduced.

In order to efficiently control one or more dummy memory cells, each of the dummy memory cells may have a required threshold voltage. Before or after an erase operation for the memory block BLKa, program operations for all or a part of the dummy memory cells may be performed. When the erase operation is performed after the program operation is performed, the dummy memory cells may have the required threshold voltage by controlling a voltage applied to dummy word lines connected to the respective dummy memory cells.

FIG. 5 is a circuit diagram illustrating a memory block BLKb according to another embodiment. The memory block BLKb may correspond to any one of the memory blocks BLK1 to BLKz of FIG. 3.

Referring to FIG. 5, the memory block BLKb includes a plurality of cell strings CS11′ to CS1m′ and CS21′ to CS2m′. Each of the plurality of cell strings CS11′ to CS1m′ and CS21′ to CS2m′ extends along a +Z direction. Each of the plurality of cell strings CS11′ to CS1m′ and CS21′ to CS2m′ includes at least one source select transistor SST, first to n-th memory cells MC1 to MCn, and at least one drain select transistor DST stacked on a substrate (not shown).

The source select transistor SST of each cell string is connected between a common source line CSL and memory cells MC1 to MCn. The source select transistors of the cell strings arranged in the same row are connected to the same source select line. The source select transistors of the cell strings CS11′ to CS1m′ arranged in a first row are connected to a first source select line SSL1. The source select transistors of the cell strings CS21′ to CS2m′ arranged in a second row are connected to a second source select line SSL2. As another embodiment, the source select transistors of the cell strings CS11′ to CS1m′ and CS21′ to CS2m′ may be commonly connected to one source select line.

The first to n-th memory cells MC1 to MCn of each cell string are connected in series between the source select transistor SST and the drain select transistor DST. Gates of the first to n-th memory cells MC1 to MCn are connected to first to the n-th word lines WL1 to WLn, respectively.

The drain select transistor DST of each cell string is connected between a corresponding bit line and the memory cells MC1 to MCn. The drain select transistors of the cell strings arranged in the row direction are connected to a drain select line extending in the row direction. The drain select transistors of the cell strings CS11′ to CS1m′ of the first row are connected to a first drain select line DSL1. The drain select transistors of the cell strings CS21′ to CS2nn′ of the second row are connected to a second drain select line DSL2.

As a result, the memory block BLKb of FIG. 5 has an equivalent circuit similar to that of the memory block BLKa of FIG. 4 except that the pipe transistor PT is excluded from each cell string.

As another embodiment, even bit lines and odd bit lines may be provided instead of first to m-th bit lines BL1 to BLm. In addition, even-numbered cell strings among the cell strings CS11′ to CS1m′ or CS21′ to CS2m′ arranged in the row direction may be connected to the even bit lines, and odd-numbered cell strings among the cell strings CS11′ to CS1m′ or CS21′ to CS2m′ arranged in the row direction may be connected to the odd bit lines, respectively.

As an embodiment, at least one of the first to n-th memory cells MC1 to MCn may be used as a dummy memory cell. In another embodiment, at least one dummy memory cell is provided in addition to the first to n-th memory cells MC1 to MCn to reduce an electric field between the source select transistor SST and the memory cells MC1 to MCn. Alternatively, at least one dummy memory cell is provided in addition to the first to n-th memory cells MC1 to MCn to reduce an electric field between the drain select transistor DST and the memory cells MC1 to MCn. As more dummy memory cells are provided, reliability of an operation for the memory block BLKb is improved, but the size of the memory block BLKb increases. As less memory cells are provided, the size of the memory block BLKb may be reduced, but the reliability of the operation for the memory block BLKb may be reduced.

In order to efficiently control one or more dummy memory cells, each of the dummy memory cells may have a required threshold voltage. Before or after an erase operation for the memory block BLKb, program operations for all or a part of the dummy memory cells may be performed. When the erase operation is performed after the program operation is performed, the dummy memory cells may have the required threshold voltage by controlling a voltage applied to the dummy word lines connected to the respective dummy memory cells.

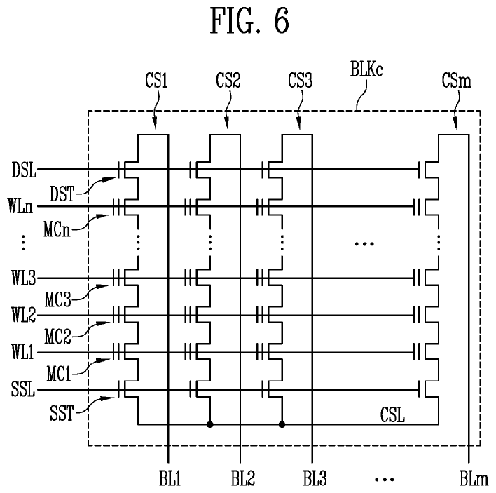

FIG. 6 is a circuit diagram illustrating a memory block BLKc in accordance with still another embodiment. The memory block BLKc may correspond to any one of the memory blocks BLK1 to BLKz included in the memory cell array 110 of FIG. 2.

Referring to FIG. 6, the memory block BKLc includes a plurality of cell strings CS1 to CSm. The plurality of cell strings CS1 to CSm may be connected to a plurality of bit lines BL1 to BLm, respectively. Each of the cell strings CS1 to CSm includes at least one source select transistor SST, first to n-th memory cells MC1 to MCn, and at least one drain select transistor DST.

Each of the select transistors SST and DST and the memory cells MC1 to MCn may have a similar structure. As an embodiment, each of the select transistors SST and DST and the memory cells MC1 to MCn may include a channel layer, a tunneling insulating film, a charge storage film, and a blocking insulating film. As an embodiment, a pillar for providing the channel layer may be provided in each cell string. As an embodiment, a pillar for providing at least one of the channel layer, the tunneling insulating film, the charge storage film, and the blocking insulating film may be provided in each cell string.

The source select transistor SST of each cell string is connected between a common source line CSL and the memory cells MC1 to MCn.

The first to n-th memory cells MC1 to MCn of each cell string are connected between the source select transistor SST and the drain select transistor DST.

The drain select transistor DST of each cell string is connected between a corresponding bit line and the memory cells MC1 to MCn.

Memory cells connected to the same word line configure one page. Each of the cell strings CS1 to CSm may be selected by selecting the drain select line DSL. One page among the cell strings may be selected by selecting any one of the word lines WL1 to WLn.

As another embodiment, even bit lines and odd bit lines may be provided instead of the first to m-th bit lines BL1 to BLm. Even-numbered cell strings among the cell strings CS1 to CSm may be connected to the even bit lines, and odd-numbered cell strings may be connected to the odd bit lines, respectively.

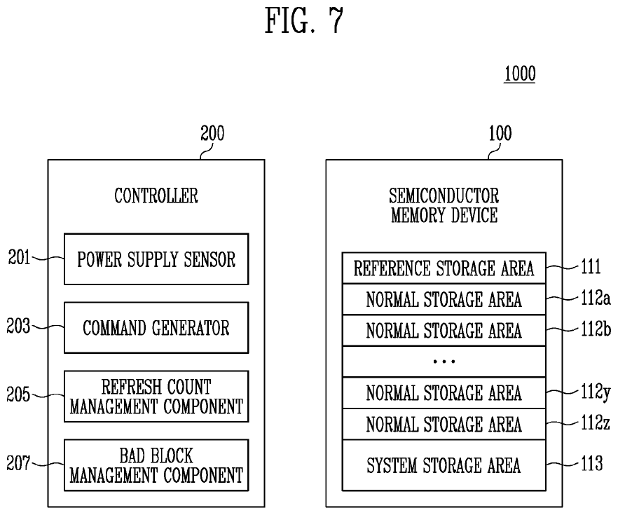

FIG. 7 is a block diagram illustrating the memory system 1000 of FIG. 1 according to an embodiment of the present disclosure.

Referring to FIG. 7, the memory system 1000 includes the semiconductor memory device 100 and the controller 200. The memory cell array of the semiconductor memory device 100 may include a reference storage area 111, a plurality of normal storage areas 112a to 112z, and a system storage area 113. In FIG. 7, a configuration other than the memory cell array of the semiconductor memory device 100 is omitted.

The reference storage area 111 may store reference data used to determine whether a threshold voltage distribution of memory cells included in the semiconductor memory device 100 is changed. In an embodiment, the reference data may be dummy data. When the memory system 1000 is switched from a turn-off state to a turn-on state, the controller 200 may read and analyze the reference data stored in the reference storage area 111, and determine whether the threshold voltage distribution of the memory cells included in the semiconductor memory device 100 is changed.

User data transferred from the host 300 of FIG. 1 may be stored in the normal storage areas 112a to 112z. Meanwhile, system information necessary for driving the memory system 1000 may be stored in the system storage area 113. For example, bad block information of the semiconductor memory device 100, a “bad block-refresh count association table,” or the like may be stored in the system storage area 113. In addition, map data indicating a relationship between a physical address and a logical address of data stored in the semiconductor memory device 100 may also be stored in the system storage area 113.

Each of the reference storage area 111, the plurality of normal storage areas 112a to 112z, and the system storage area 113 shown in FIG. 7 may have an arbitrary size. In an embodiment, each of the reference storage area 111, the plurality of normal storage areas 112a to 112z, and the system storage area 113 may correspond to a memory block. That is, the reference storage area 111 may be a memory block in which the reference data is stored. Each of the normal storage areas 112a to 112z may be a memory block in which the user data is stored. The system storage area 113 may be a memory block in which the system information is stored.

The controller 200 may include a power supply sensor 201, a command generator 203, a refresh count manager 205, and a bad block manager 207.

The power supply sensor 201 may sense that power is supplied to the memory system 1000 and thus the memory system 1000 is in a turn-on state. The command generator 203 may generate a command for controlling the semiconductor memory device 100. For example, the command generator 203 may generate a read command, a program command, or an erase command.

The refresh count manager 205 may count the number of times the reference data stored in the reference storage area 111 is refreshed. More specifically, when the memory system 1000 is switched from the turn-off state to the turn-on state, the refresh count manager 205 may load therein the bad block-refresh count association table stored in the system storage 113 of the semiconductor memory device 100. Meanwhile, the refresh count manager 205 may receive the reference data stored in the reference storage area 111 of the semiconductor memory device 100. The refresh count manager 205 may analyze the reference data to determine whether the threshold voltage distribution of the memory cells included in the semiconductor memory device 100 is changed. When it is determined that the threshold voltage distribution of the memory cells is changed, the refresh count manager 205 may refresh the reference data stored in the reference storage area 111. Meanwhile, the refresh count manager 205 may update a refresh count value included in the bad block-refresh count association table according to the refresh operation. The refresh count value may indicate the accumulated number of times the refresh operation is performed for the reference storage area 111. For example, when the reference data stored in the reference storage area 111 is refreshed, the refresh count manager 205 may increase the refresh count value included in the bad block-refresh count association table by 1.

The bad block manager 207 may manage information related to a bad block among the plurality of memory blocks included in the semiconductor memory device 100. When the memory system 100 is switched from the turn-off state to the turn-on state, the bad block manager 207 may load therein the bad block information stored in the system storage area 113. When a new bad block is generated while the memory system 1000 operates, the bad block manager 207 may update the loaded bad block information and store the updated bad block information in the system storage area 113.

Meanwhile, the refresh count manager 205 may receive the updated bad block information from the bad block manager 207 and update the number of bad blocks included in the bad block-refresh count association table. The bad block-refresh count association table may store the number of bad blocks corresponding to a plurality of power-on sequences and a refresh count value corresponding to each power-on sequence. The “power-on sequence” may mean a period until the memory system 1000 is turned off after the memory system 1000 is turned on. For example, a first power-on sequence may mean a sequence in which the memory system 1000 is initially turned on and operates after the memory system 1000 is produced. As the memory system 1000 is turned off after the memory system 1000 is initially turned on, the first power-on sequence may be ended. Thereafter, when the memory system 1000 is turned on again, a second power-on sequence is started. As described above, the controller 200 selectively performs the refresh operation on the reference data stored in the reference storage area 111 each time the memory system 1000 is turned on, and records the accumulated refresh count value corresponding to the corresponding power-on sequence in the bad block-refresh count association table. Meanwhile, the controller 200 records the accumulated number of bad blocks in the bad block-refresh count association table for each power-on sequence. Therefore, the bad block-refresh count association table may include the number of bad blocks and the refresh count value corresponding to each power-on sequence. Accordingly, a correlation between the refresh count value of the reference data stored in the reference storage area 111 and the number of bad blocks may be analyzed based on data of the bad block-refresh count association table.

Data stored in the semiconductor memory device 100 may be affected by stress due to heat generated in the memory system 1000. When a soldering process is performed to mount the semiconductor memory device 100 of a form of a small chip on a printed circuit board (PCB), this is referred to as surface mount technology (SMT). In such a mounting process, stress due to a high temperature may be transferred to the semiconductor memory device 100. This may cause a retention defect in the memory cells included in the semiconductor memory device 100.

Because of the mounting process of the memory system 1000, such high temperature stress may inevitably occur. To solve such a problem, data may be written to the semiconductor memory device 100 after the high temperature stress occurs, or data requiring reliability, such as system data, may be programmed in the semiconductor memory device 100 in a single-level cell (SLC) method.

However, such high temperature stress does not necessarily occur only in a production process, but may also occur in a transportation process after product shipment of the memory system 1000. In particular, when such high temperature stress is applied while the memory system 1000 is powered off, it is difficult to know a time point at which the high temperature stress is applied to the memory system 1000.

According to the present disclosure, some of a storage area of the semiconductor memory device 100 is allocated as the reference storage area, and reference data for determining whether data is retained or not or a degree of retention is stored in the reference storage area. Meanwhile, when the memory system 1000 is switched from the turn-off state to the turn-on state, the reference data stored in the reference storage area is read out. According to a degree of change of the read data, whether the high temperature stress is applied to the semiconductor memory device 100 while the memory system 1000 is in the turn-off state or a degree of the high temperature stress may be analyzed. Accordingly, a cause of deterioration of the data stored in the semiconductor memory device 100 may be easily recognized.

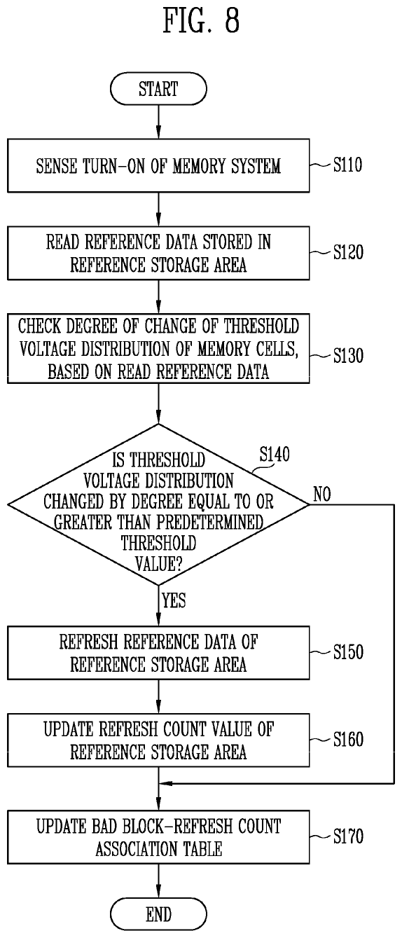

FIG. 8 is a flowchart illustrating a method of operating a controller according to an embodiment of the present disclosure. The operation illustrated in FIG. 8 will be described with reference to FIGS. 1 and 7.

Referring to FIG. 8, when the memory system 1000 is switched from the turn-off state to the turn-on state, the controller 200 may sense that the memory system 1000 is turned on (S110). Thereafter, the controller 200 reads out the reference data stored in the reference storage area 111 of the semiconductor memory device 100 (S120). The controller 200 checks the degree of change of the threshold voltage distribution of the memory cells included in the semiconductor memory device 100, based on the reference data (S130).

When the threshold voltage distribution of the memory cells is changed by the degree equal to or greater than a predetermined threshold value (S140: Yes), the controller 200 refreshes the reference data stored in the reference storage area 111 (S150). Thereafter, the controller 200 updates the refresh count value of the reference storage area 111 (S160). In step S160, the controller 200 may increase the refresh count value of the reference storage area 111 by 1. Thereafter, the controller 200 may update the refresh count value included in the bad block-refresh count association table based on the updated refresh count value. When the refresh count value is increased by 1 in step S160, in step S170, the refresh count value included in the bad block-refresh count association table corresponding to the corresponding power-on sequence may also be increased by 1.

When the threshold voltage distribution of the memory cells is not changed by the degree equal to or greater than the predetermined threshold value (S140: No), the refresh operation on the data stored in the reference storage area 111 is not performed. Therefore, in this case, the bad block-refresh count association table may be updated in step S170 without increasing the refresh count value corresponding to the corresponding power-on sequence.

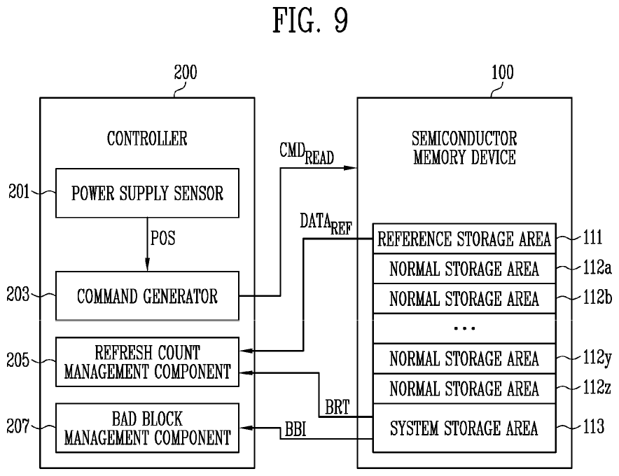

FIG. 9 is a diagram illustrating steps S110 to S130 of FIG. 8.

Referring to FIG. 9, when the memory system 1000 is turned on, the power supply sensor 201 senses the turn-on state of the memory system 1000 (S110). The power supply sensor 201 generates a power-on signal POS indicating that the memory system 1000 is turned on, and transfers the power-on signal POS to the command generator 203.

The command generator 203 generates a read command CMD_{READ} for reading reference data DATA_{REF} stored in the reference storage area 111 in response to the power-on signal POS. The read command CMD_{READ} is transferred to the semiconductor memory device 100. The semiconductor memory device 100 reads the reference data DATA_{REF} stored in the reference storage area 111 in response to the read command CMD_{READ} and transfers the reference data DATA_{REF} to the refresh count manager 205 in the controller 200. In such a method, the controller 200 may read the reference data DATA_{REF} stored in the reference storage area 111 (S120).

Meanwhile, although not shown in FIG. 9, the command generator 203 may generate a read command for reading a bad block-refresh count association table BRT and bad block information BBI stored in the system storage area 113. In response to the read command, the semiconductor memory device 100 may read the bad block-refresh count association table BRT and the bad block information BBI stored in the system storage area 113, and transfer the bad block-refresh count association table BRT and the bad block information BBI to the controller 200. The bad block-refresh count association table BRT may be transferred to the refresh count manager 205. Meanwhile, the bad block information BBI may be transferred to the bad block manager 207.

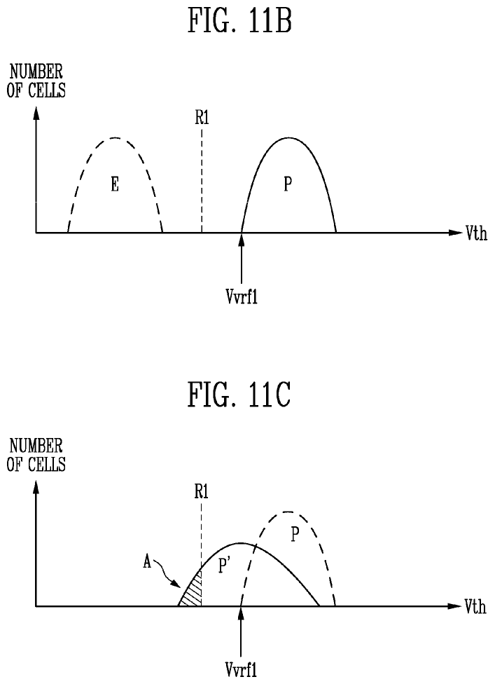

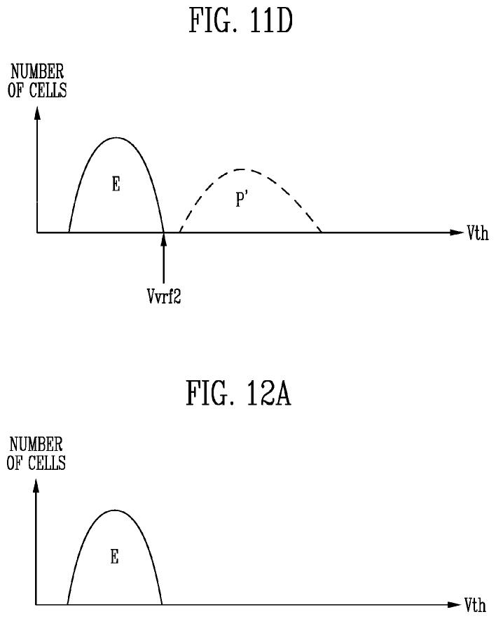

The refresh count manager 205 determines whether the threshold voltage distribution of the memory cells included in the semiconductor memory device 100 is changed, based on the reference data DATA_{REF} (S130). In a state in which the memory system 1000 is turned off, the threshold voltage distribution of the memory cells included in the semiconductor memory device 100 may be changed due to high temperature stress or the like. In a state in which the memory system 1000 is turned off, a change pattern of the threshold voltage distribution of all memory cells included in the semiconductor memory device 100 may be the same. Therefore, a change of the threshold voltage distribution of all memory cells included in the semiconductor memory device 100 may be determined by checking whether the threshold voltage distribution of the memory cells included in the reference storage area 111 is changed among all memory cells included in the semiconductor memory device 100. Specific embodiments of determining whether the threshold voltage distribution of the memory cells included in the semiconductor memory device 100 is changed, based on the reference data DATA_{REF} may be described in detail with reference to FIGS. 11A to 14D.

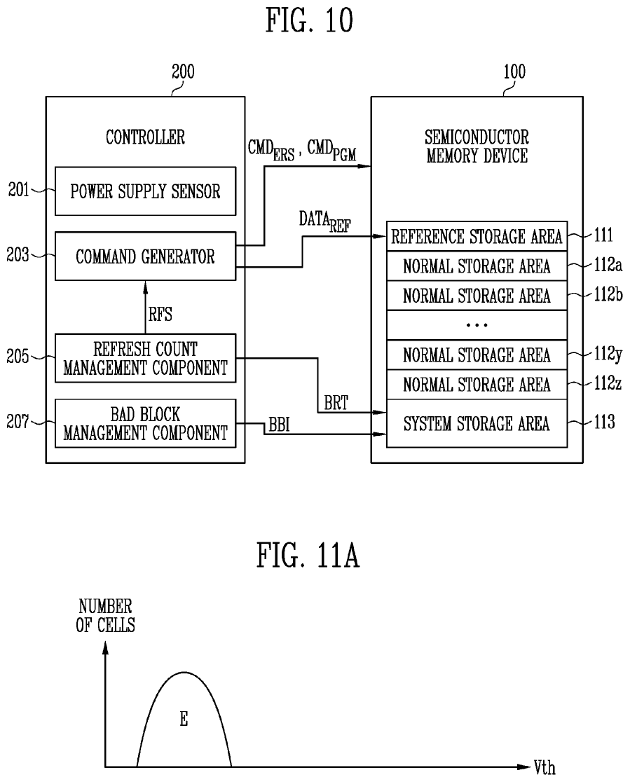

When the threshold voltage distribution of the memory cells included in the semiconductor memory device 100 is changed by the degree equal to or greater than the predetermined threshold value (S140: Yes), the controller 200 refreshes the reference data DATA_{REF} stored in the reference storage area 111 as described in FIG. 8 (S150), and updates the refresh count value of the reference storage area 111 (S160). In addition, the controller 200 updates the bad block-refresh count association table with the updated refresh count value (S170). Steps S150 to S170 will be further described with reference to FIG. 10.

FIG. 10 is a diagram illustrating steps S150 to S170 of FIG. 8.

When the threshold voltage distribution of the memory cells included in the semiconductor memory device 100 is changed by the degree equal to or greater than the predetermined threshold value (S140: Yes), the refresh count manager 205 generates a refresh signal RFS and transfers the refresh signal RFS to the command generator 203. The command generator S203 may transfer commands for refreshing the reference data DATA_{REF} stored in the reference storage area 111 to the semiconductor memory device 100 in response to the refresh signal RFS. For example, the command generator 203 may transfer at least one of an erase command CMD_{ERS} for erasing the data stored in the reference storage area 111 and a program command CMD_{PGM} for programming reference data DATA_{REF} in the reference storage area 111 to the semiconductor memory device 100. In addition, the command generator 203 may transfer the reference data DATA_{REF} to be programmed in the reference storage area 111 together with the program command CMD_{PGM} to the semiconductor memory device 100. In response to the command, the semiconductor memory device 100 may restore the reference data DATA_{REF} in the reference storage area 111. In such a method, the controller 200 may refresh the reference data DATA_{REF} stored in the reference storage area 111 (S150).

Meanwhile, the refresh count manager 205 may update the refresh count value after generating the refresh signal RFS (S160). As described above, the refresh count manager 205 may update the refresh count value by increasing the refresh count value by 1. Meanwhile, the refresh count manager 205 may update the bad block-refresh count association table BRT based on the updated refresh count value.

Meanwhile, when a bad block is additionally generated in a state in which the memory system 1000 is turned on, the bad block manager 207 may transfer updated bad block information BBI including information on the added bad block to the refresh count manager 205. The refresh count manager 205 may update the bad block-refresh count association table BRT, based on the bad block information BBI. The refresh count manager 205 may update the number of bad blocks included in the bad block-refresh count association table BRT based on the updated bad block information BBI.

As a result, the refresh count manager 205 may update the bad block-refresh count association table BRT based on the updated refresh count value and the received bad block information BBI. The updated bad block-refresh count association table BRT may be stored in the system storage area 113 of the semiconductor memory device 100. Therefore, the bad block-refresh count association table BRT stored in the system storage area 113 is updated.

Additionally, the bad block manager 207 may store the updated bad block information BBI in the system storage area 113 of the semiconductor memory device 100.

FIGS. 11A to 11D are diagrams illustrating step S130 of FIG. 8 according to an embodiment.

FIG. 11A shows a threshold voltage distribution of an erase state E. According to an embodiment of the present disclosure, the reference data DATA_{REF} may be stored in the reference storage area 111 in a single-level cell (SLC) program method. Accordingly, as shown in FIG. 11B, memory cells having a threshold voltage of the erase state E may be programmed to a program state P.

In the SLC program method, for example, a memory cell in the erase state E may store a bit of “1,” and a memory cell in the program state P may store a bit of “0.” In the embodiment of FIG. 11B, the reference data DATA_{REF} may be data having the bit of “0.” Therefore, all memory cells having the threshold voltage of the erase state E are programmed to the program state P. In this case, the program operation may be performed based on a first verify voltage Vvrf1.

Immediately after the program operation of the reference data DATA_{REF} is completed, the memory cells have a threshold voltage distribution as shown in FIG. 11B. In this case, when a read operation is performed by a read voltage R1, data having only the bit of “0” may be read. Therefore, when the memory cells included in the reference storage area 111 have the threshold voltage distribution as shown in FIG. 11B, only the bit of “0” may be included in the reference data DATA_{REF} that is transferred to the controller 200 by the read operation S120. As a result, in step S130 of FIG. 8, it may be determined that the threshold voltage distribution of the memory cells is not changed.

FIG. 11C shows a state of memory cells of which the threshold voltage distribution is deteriorated after the program operation. In FIG. 11C, the threshold voltage distribution of the memory cells is changed from the program state P to a deteriorated program state P′ due to a retention phenomenon. For example, the threshold voltage distribution of the memory cells may be changed from the program state P to the deteriorated program state P′ due to high temperature stress. In this case, when the read operation is performed by the read voltage R1, memory cells corresponding to a hatched area “A” may be read as storing the bit of “1.” Therefore, when the memory cells included in the reference storage area 111 have the threshold voltage distribution as shown in FIG. 11C, the bit of “0” and the bit of “1” may be mixed in the reference data DATA_{REF} transferred to the controller 200 by the read operation S120. The greater the number of bits of “1” included in the reference data DATAREF, the greater the degree of change of the threshold voltage distribution of the memory cells. Therefore, it may be determined whether the degree of change of the threshold voltage distribution of the memory cells exceeds the threshold value by comparing the number of bits of “1” included in the reference data DATA_{REF} with a predetermined threshold number.

When the number of bits of “1” included in the reference data DATA_{REF} is equal to or greater than the predetermined threshold number, the refresh count manager 205 may determine that the threshold voltage distribution of the memory cells is changed by the degree equal to or greater than the predetermined threshold value. Therefore, in this case, the controller 200 may refresh the reference data DATA_{REF} stored in the reference storage area 111 (S150), and update the refresh count value of the reference storage area 111 (S160).

When the number of bits of “1” included in the reference data DATA_{REF} is less than the predetermined threshold number, the refresh count manager 205 may determine that the threshold voltage distribution of the memory cells is not changed by the degree equal to or greater than the predetermined threshold value. Therefore, in this case, the controller 200 may not refresh the reference data DATA_{REF} stored in the reference storage area 111.

FIG. 11D shows the change of the threshold voltage distribution of the memory cells during an erase operation for the refresh operation. The command generator 203 may first transfer the erase command CMD_{ERS} to the semiconductor memory device 100. The semiconductor memory device 100 may erase the reference data DATA_{REF} stored in the memory cells based on an erase verify voltage Vvrf2. Accordingly, data stored in the memory cells having the threshold voltage of the deteriorated program state P′ are erased and the memory cells are changed to the erase state E.

Thereafter, the command generator 203 may transfer the program command CMD_{PGM} and new reference data DATA_{REF} to the semiconductor memory device 100. In this case, the new reference data DATA_{REF} may be data including the bit of “0.” Accordingly, the semiconductor memory device 100 reprograms the reference data DATA_{REF} including only the bit of “0” in the reference storage area 111. As a result, the memory cells may be programmed to have the threshold voltage distribution shown in FIG. 11B.

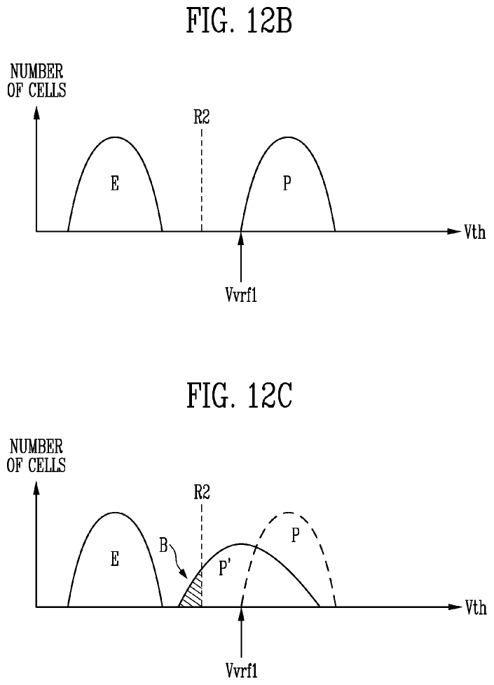

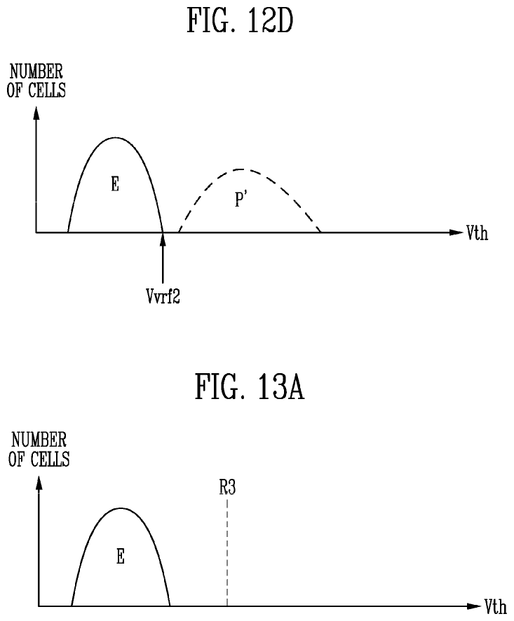

FIGS. 12A to 12D are diagrams illustrating step S130 of FIG. 8 according to another embodiment.

FIG. 12A shows a threshold voltage distribution of an erase state E. According to an embodiment of the present disclosure, the reference data DATA_{REF} may be stored in the reference storage area 111 in the SLC program method. Accordingly, as shown in FIG. 12B, some of memory cells having a threshold voltage of the erase state E may be programmed to a program state P. For example, half of the memory cells included in the reference storage area 111 may be programmed to the program state P. In this case, the remaining half of the memory cells maintain the erase state E.

In the SLC program method, for example, a memory cell of the erase state E may store a bit of “1,” and a memory cell of the program state P may store a bit of “0.” In the embodiment of FIG. 12B, the reference data DATA_{REF} may be data in which the bits of “0” and “1” exist at a predetermined ratio. In an embodiment, the ratio of the number of bits of “0” to the number of bits of “1” included in the reference data DATA_{REF} may be 1 to 1. Therefore, immediately after the program operation for the reference data DATA_{REF} is completed, the memory cells of the reference storage area 111 have a threshold voltage distribution as shown in FIG. 12B. In this case, when a read operation is performed using a read voltage R2, the number of bits of “0” and the number of bits of “1” may be the same. Therefore, when the memory cells included in the reference storage area 111 have the threshold voltage distribution as shown in FIG. 12B, the number of bits of “0” and the number of bits of “1” included in the reference data DATA_{REF} transferred to the controller 200 by the read operation S120 may be determined to be the same. As a result, in this case, in step S130 of FIG. 8, it may be determined that the threshold voltage distribution of the memory cells is not changed.

FIG. 12C shows a state of memory cells of which the threshold voltage distribution is deteriorated after the program operation. In FIG. 12C, the threshold voltage distribution of the programmed memory cells is changed from the program state P to a deteriorated program state P′ due to a retention phenomenon. In this case, when the read operation is performed by the read voltage R2, memory cells corresponding to a hatched area “B” may be read as storing the bit of “1.” Therefore, when the memory cells included in the reference storage area 111 have the threshold voltage distribution as shown in FIG. 12C, the ratio of the number of bits of “0” to the number of bits of “1” included in the reference data DATA_{REF} transferred to the controller 200 by the read operation S120 may be determined to be changed. That is, the number of bits of “1” may be greater than the number of bits of “0.”

In the reference data DATA_{REF}, when the increased number of bits of “1” included in the reference data DATA_{REF} is equal to or greater than a predetermined threshold number, the refresh count manager 205 may determine that the threshold voltage distribution of the memory cells is changed by the degree equal to or greater than the predetermined threshold value. Therefore, in this case, the controller 200 may refresh the reference data DATA_{REF} stored in the reference storage area 111 (S150), and update the refresh count value of the reference storage area 111 (S160).

In the reference data DATA_{REF}, when the increased number of bits of “1” included in the reference data DATA_{REF} is less than the predetermined threshold number, the refresh count manager 205 may determine that the threshold voltage distribution of the memory cells is not changed by the degree equal to or greater than the predetermined threshold value. Therefore, in this case, the controller 200 may not refresh the reference data DATA_{REF} stored in the reference storage area 111.

FIG. 12D shows the change of the threshold voltage distribution of the memory cells during an erase operation for the refresh operation. The command generator 203 may first transfer the erase command CMD_{ERS} to the semiconductor memory device 100. The semiconductor memory device 100 may erase the reference data DATA_{REF} stored in the memory cells based on an erase verify voltage Vvrf2. Accordingly, data stored in the memory cells having the threshold voltage of the deteriorated program state P′ are erased and the memory cells are changed to the erase state E.

Thereafter, the command generator 203 may transfer the program command CMD_{PGM} and new reference data DATA_{REF} to the semiconductor memory device 100. In this case, the new reference data DATA_{REF} may be data corresponding to the number of bits of “0” and the number of bits of “1” that are the same. Accordingly, the semiconductor memory device 100 reprograms the reference data DATA_{REF} in the reference storage area 111. As a result, the memory cells of the reference storage area 111 may be programmed to have the threshold voltage distribution shown in FIG. 12B.

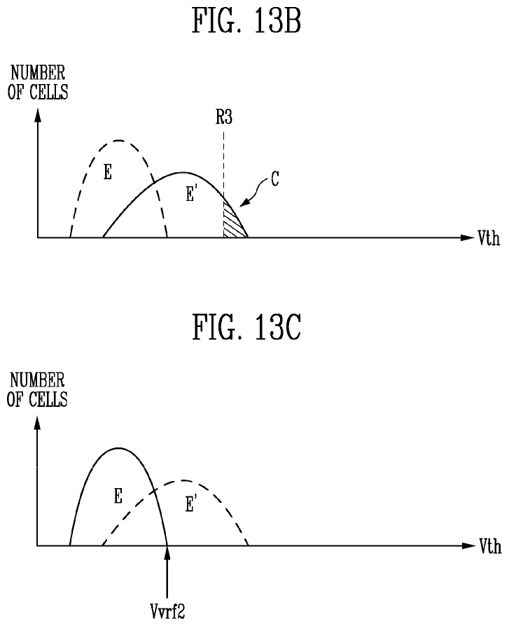

FIGS. 13A to 13C are diagrams illustrating step S130 of FIG. 8 according to still another embodiment.

FIG. 13A shows a threshold voltage distribution of an erase state E. According to an embodiment of the present disclosure, the reference data DATA_{REF} may be stored in the reference storage area 111 in the SLC program method.

In the SLC program method, for example, a memory cell in the erase state E may store a bit of “1,” and a memory cell in the program state P may store a bit of “0.” In the embodiment of FIG. 13A and 13B, the reference data DATA_{REF} may be data having the bit of “1.” Therefore, the threshold voltage distribution of the erase state E is maintained. In this case, when the read operation is performed using a read voltage R3, data having only the bit of “1” may be read. Therefore, when the memory cells included in the reference storage area 111 have the threshold voltage distribution as shown in FIG. 13A, only the bit of “1” may be included in the reference data DATA_{REF} transferred to the controller 200 by the read operation S120. As a result, in this case, in step S130 of FIG. 8, it may be determined that the threshold voltage distribution of the memory cells is not changed.

FIG. 13B shows a state of the memory cells of which the threshold voltage distribution is deteriorated after the erase operation. In FIG. 13B, the threshold voltage distribution of the memory cells is changed from the erase state E to a deteriorated erase state E′ due to a disturb phenomenon. In this case, when the read operation is performed by the read voltage R3, memory cells corresponding to a hatched area “C” may be read as storing the bit of “0.” Therefore, when the memory cells included in the reference storage area 111 have the threshold voltage distribution as shown in FIG. 13B, the bit of “0” and the bit of “1” may be mixed in the reference data DATA_{REF} transferred to the controller 200 by the read operation S120.

When the number of bits of “0” included in the reference data DATA_{REF} is equal to or greater than a predetermined threshold number, the refresh count manager 205 may determine that the threshold voltage distribution of the memory cells is changed by the degree equal to or greater than the predetermined threshold value. Therefore, in this case, the controller 200 may refresh the reference data DATA_{REF} stored in the reference storage area 111 (S150), and update the refresh count value of the reference storage area 111 (S160).

When the number of bits of “0” included in the reference data DATA_{REF} is less than the predetermined threshold number, the refresh count manager 205 may determine that the threshold voltage distribution of the memory cells is not changed by the degree equal to or greater than the predetermined threshold value. Therefore, in this case, the controller 200 may not refresh the reference data DATA_{REF} stored in the reference storage area 111.

FIG. 13C shows the change of the threshold voltage distribution of the memory cells during an erase operation for the refresh operation. The command generator 203 may first transfer the erase command CMD_{ERS} to the semiconductor memory device 100. The semiconductor memory device 100 may erase the reference data DATA_{REF} stored in the memory cells based on an erase verify voltage Vvrf2. Accordingly, data stored in the memory cells having the threshold voltage of the deteriorated erase state E′ are erased and the memory cells are changed to the erase state E.

Thereafter, the command generator 203 may not transfer a separate program command CMD_{PGM} to the semiconductor memory device 100. In this case, since all threshold voltages of the memory cells included in the reference storage area 111 correspond to the erase state E, the reference data DATA_{REF} including only the bit of “1” is stored in the reference storage area 111.

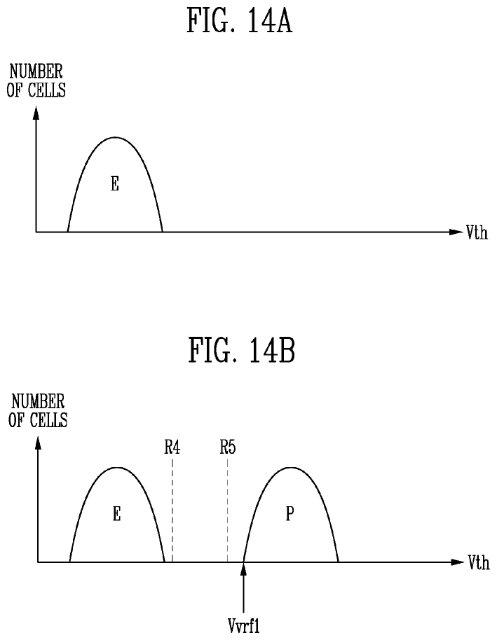

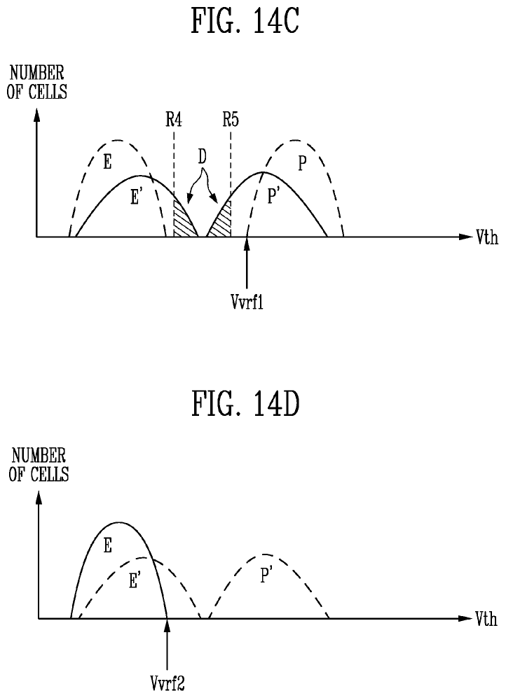

FIGS. 14A to 14D are diagrams illustrating step S130 of FIG. 8 according to still another embodiment.

FIG. 14A shows a threshold voltage distribution of an erase state E. According to an embodiment of the present disclosure, the reference data DATA_{REF} stored in the reference storage area 111 may be stored in the SLC program method. Accordingly, as shown in FIG. 14B, some of memory cells having a threshold voltage of the erase state E may be programmed to a program state P. For example, half of the memory cells included in the reference storage area 111 may be programmed to the program state P. In this case, the remaining half of the memory cells in the reference storage area 111 maintain the erase state E.

In the SLC program method, for example, a memory cell in the erase state E may store a bit of “1,” and a memory cell in the program state P may store a bit of “0.” In the embodiment of FIG. 14B, the reference data DATA_{REF} may be data in which the bits of “0” and “1” exist at a predetermined ratio. In an embodiment, the ratio of the number of bits of “0” to the number of bits of “1” included in the reference data DATA_{REF} may be 1 to 1. Therefore, immediately after the program operation for the reference data DATA_{REF} is completed, the memory cells have a threshold voltage distribution as shown in FIG. 14B. In this case, when the read operation is performed by the read voltage R1, the number of bits of “0” and the number of bits of “1” may be the same. Meanwhile, a memory cell having a threshold voltage between a read voltage R4 and a read voltage R5 may not exist.

The controller 200 may control the semiconductor memory device 100 to perform each of a read operation based on the read voltage R4 and a read operation based on the read voltage R5. The controller 200 may determine the number of memory cells having the threshold voltage between the read voltage R4 and the read voltage R5 by comparing the reference data DATA_{REF} read by the read voltage R4 and the reference data DATA_{REF} read by the read voltage R5. For example, a threshold voltage of a memory cell indicating the bit of “0” in the reference data DATA_{REF} read by the read voltage R4 and indicating the bit of “1” in the reference data DATA_{REF} read by the read voltage R5 exists between the read voltage R4 and the read voltage R5. In such a method, the number of memory cells having the threshold voltage between the read voltage R4 and the read voltage R5 may be determined.

Therefore, when the memory cells included in the reference storage area 111 have the threshold voltage distribution as shown in FIG. 14B, the number of memory cells having the threshold voltage between the read voltage R4 and the read voltage R5 may be zero. As a result, in this case, in step S130 of FIG. 8, it may be determined that the threshold voltage distribution of the memory cells is not changed.

FIG. 14C shows a state of memory cells of which a threshold voltage distribution is deteriorated after the program operation. In FIG. 14C, the threshold voltage distributions of the memory cells are changed from the program state P and the erase state E to a deteriorated program state P′ and a deteriorated erase state E′ due to a retention phenomenon and a disturb phenomenon, respectively. In this case, when the read operation is performed using the read voltage R4, memory cells corresponding to a hatched area “D” may be read as storing the bit of “0.” In addition, when the read operation is performed using the read voltage R5, the memory cells corresponding to the hatched area “D” may be read as storing the bit of “1.”

When the number of memory cells corresponding to the hatched area “D” is equal to or greater than a predetermined threshold number, the refresh count manager 205 may determine that the threshold voltage distribution of the memory cells is changed by the degree equal to or greater than the predetermined threshold value. Therefore, in this case, the controller 200 may refresh the reference data DATA_{REF} stored in the reference storage area 111 (S150), and update the refresh count value of the reference storage area 111 (S160).

When the number of memory cells corresponding to the hatched area “D” is less than the predetermined threshold number, the refresh count manager 205 may determine that the threshold voltage distribution of the memory cells is not changed by the degree equal to or greater than the predetermined threshold value. Therefore, in this case, the controller 200 may not refresh the reference data DATA_{REF} stored in the reference storage area 111.

FIG. 14D shows the change of the threshold voltage distribution of the memory cells during an erase operation for the refresh operation. The command generator 203 may first transfer the erase command CMD_{ERS} to the semiconductor memory device 100. The semiconductor memory device 100 may erase the reference data DATA_{REF} stored in the memory cells based on an erase verify voltage Vvrf2. Accordingly, data stored in the memory cells having the threshold voltage of the deteriorated program state P′ and the deteriorated erase state E′ are erased and the memory cells are changed to the erase state E.

Thereafter, the command generator 203 may transfer the program command CMD_{PGM} and new reference data DATAREF to the semiconductor memory device 100. In this case, the new reference data DATA_{REF} may be data corresponding to the number of bits of “0” and the number of bits of “1” that are the same. Accordingly, the semiconductor memory device 100 reprograms the new reference data DATA_{REF} in the reference storage area 111. As a result, the memory cells may be programmed to have the threshold voltage distribution shown in FIG. 14B.

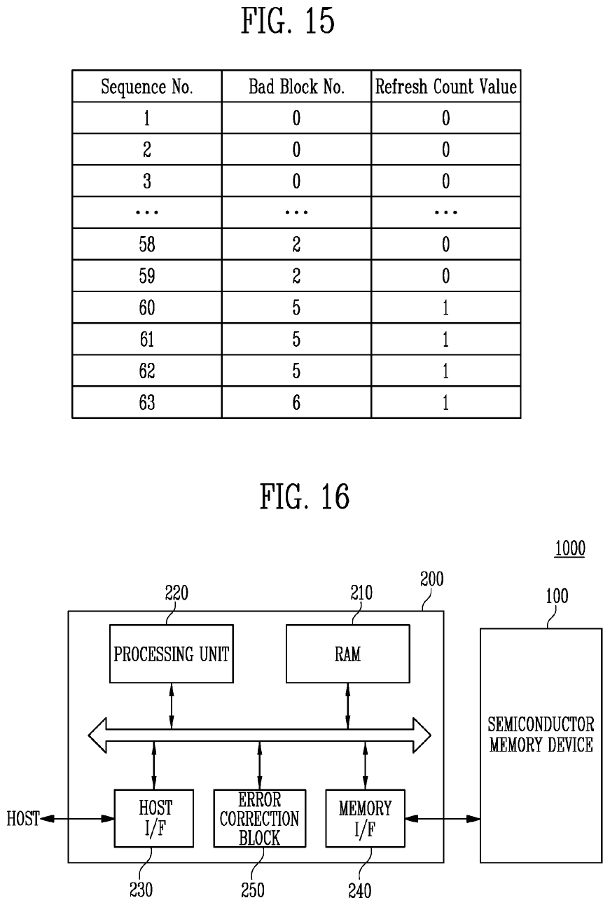

FIG. 15 is a diagram illustrating a bad block-refresh count association table according to an embodiment of the present disclosure.

Referring to FIG. 15, the bad block-refresh count association table includes a first column indicating a sequence number, a second column indicating the number of bad blocks, and a third column indicating a refresh count value.

The sequence number indicates a power-on sequence described above. In the first column, a sequence number 1 indicates a first power-on sequence in which the memory system 1000 is turned on first after the memory system 1000 is manufactured.

The number of bad blocks corresponding to the sequence number 1 is zero, which means that the number of bad blocks generated during the first power-on sequence is zero. In addition, a refresh count value corresponding to the sequence number 1 is 0, which means that a refresh operation is not performed on the reference data DATA_{REF} stored in the reference storage area 111 in the first power-on sequence.

The number of bad blocks corresponding to a sequence number 2 is zero, which means that the number of bad blocks generated during a second power-on sequence is zero. In addition, a refresh count value corresponding to the sequence number 2 is 0, which means that the refresh operation is not performed on the reference data DATA_{REF} stored in the reference storage area 111 in the second power-on sequence.

The number of bad blocks corresponding to a sequence number 3 is zero, which means that the number of bad blocks generated during a third power-on sequence is zero. In addition, a refresh count value corresponding to the sequence number 3 is 0, which means that the refresh operation is not performed on the reference data DATA_{REF} stored in the reference storage area 111 in the third power-on sequence. In such a manner, when the memory system 1000 is switched from the turn-off state to the turn-on state, a new power-on sequence may be started, and a refresh count value and the number of bad blocks in a corresponding power-on sequence may be updated and included in the bad block-refresh count association table.

Referring to FIG. 15, the number of bad blocks corresponding to a sequence number 58 is two. This means that the accumulated number of bad blocks generated up to a fifth-eighth power-on sequence is two. Meanwhile, a refresh count value corresponding to the sequence number 58 is 0. This means that the refresh operation is not yet performed for the reference storage area 111 from the first power-on sequence to the fifth-eighth power-on sequence. This is the same as in a fifth-ninth power-on sequence.

Meanwhile, the number of bad blocks corresponding to a sequence number 60 is five. This means that the accumulated number of bad blocks generated up to a sixtieth power-on sequence is five. Since the number of bad blocks corresponding to the sequence number 59 is two, the number of bad blocks generated in the sixtieth power-on sequence is three. Meanwhile, a refresh count value corresponding to the sequence number 60 is 1. Since the refresh operation is not performed until the fifty-ninth power-on sequence, this means that the refresh operation is performed in the reference storage area 111 in the sixtieth power-on sequence.

In the sixtieth power-on sequence, the refresh operation is performed in the reference storage area 111, and the number of bad blocks is increased by 3. This may mean that an important event such as high temperature stress occurs in the memory system 1000 before the sixtieth power-on sequence is started after the fifty-ninth power-on sequence is ended and the memory system 1000 is turned off.

As described above, according to the method according to the embodiments of the present disclosure, the refresh operation is performed by determining whether the threshold voltage distribution of the memory cells of the reference storage area 111 is changed at the beginning of a power-on sequence of the memory system 1000, and the refresh count value of the bad block-refresh count association table is updated when the refresh operation is performed for the reference storage area 111.

Information on the number of bad blocks generated in each power-on sequence is also updated in the bad block-refresh count association table. Therefore, the refresh count value and the number of bad blocks may be compared in each power-on sequence by referring to the bad block-refresh count association table. Through such comparison, the occurrence of an event during power-off of the memory system 1000 may be checked.

FIG. 16 is a block diagram illustrating an example of the controller 200 shown in FIG. 1.

Referring to FIG. 16, the controller 200 is connected to a semiconductor memory device 100 and a host HOST. The semiconductor memory device 100 may be the semiconductor memory device described with reference to FIG. 2. The controller 200 corresponds to the controller 200 of FIG. 1 or 7. Hereinafter, a repetitive description is omitted.

The controller 200 is configured to access the semiconductor memory device 100 in response to a request from the host Host. For example, the controller 200 is configured to control read, write, erase, and background operations of the semiconductor memory device 100. The controller 200 is configured to provide an interface between the semiconductor memory device 100 and the host HOST. The controller 200 is configured to drive firmware for controlling the semiconductor memory device 100.

The controller 200 includes a random access memory (RAM) 210, a processing unit 220, a host interface 230, a memory interface 240, and an error correction block 250. The RAM 210 is used as at least one of an operation memory of the processing unit 220, a cache memory between the semiconductor memory device 100 and the host Host, and a buffer memory between the semiconductor memory device 100 and the host Host. In addition, the RAM 210 may also be used as a command queue that temporarily stores commands to be transferred to the semiconductor memory device 100.

The processing unit 220 controls an overall operation of the controller 200. According to an embodiment, the power supply sensor 201, the command generator 203, the refresh count manager 205, and the bad block manager 207 shown in FIG. 9 may be implemented in a form of firmware executed by the processing unit 220.

The host interface 230 includes a protocol for performing data exchange between the host Host and the controller 200. As an embodiment, the controller 200 is configured to communicate with the host Host through at least one of various interface protocols such as a universal serial bus (USB) protocol, a multimedia card (MMC) protocol, a peripheral component interconnection (PCI) protocol, a PCI-express (PCI-E) protocol, an advanced technology attachment (ATA) protocol, a serial ATA protocol, a parallel ATA protocol, a small computer system interface (SCSI) protocol, an enhanced small disk interface (ESDI) protocol, an integrated drive electronics (IDE) protocol, and a private protocol.

The memory interface 240 interfaces with the semiconductor memory device 100. For example, the memory interface 1240 includes a NAND flash interface or a NOR flash interface.

The error correction block 250 is configured to detect and correct an error of data received from the semiconductor memory device 100 using an error correcting code (ECC). The processing unit 220 may control the semiconductor memory device 100 to adjust a read voltage and perform re-reading according to an error detection result of the error correction block 250.

The controller 200 and the semiconductor memory device 100 may be integrated into one semiconductor device. As an embodiment, the controller 200 and the semiconductor memory device 100 may be integrated into one semiconductor device to form a memory card such as a PC card (e.g., personal computer memory card international association (PCMCIA)), a compact flash card (CF), a smart media card (SM or SMC), a memory stick, a multimedia card (e.g., MMC, RS-MMC, or MMCmicro), an SD card (e.g., SD, miniSD, microSD, or SDHC), a universal flash storage (UFS), or the like.

The controller 200 and the semiconductor memory device 100 may be integrated into one semiconductor device to form a semiconductor drive (e.g., solid state drive (SSD)). The SSD includes the memory system 1000 configured to store data in a semiconductor memory. When the memory system 1000 including the controller 200 and the semiconductor memory device 100 is used as the SSD, an operation speed of the host HOST connected to the memory system 1000 is dramatically improved.

As another example, the memory system 1000 including the controller 200 and the semiconductor memory device 100 is provided as one of various components of an electronic device, such as a computer, an ultra-mobile PC (UMPC), a workstation, a net-book, a personal digital assistants (PDA), a portable computer, a web tablet, a wireless phone, a mobile phone, a smart phone, an e-book, a portable multimedia player (PMP), a portable game machine, a navigation device, a black box, a digital camera, a 3-dimensional television, a digital audio recorder, a digital audio player, a digital picture recorder, a digital picture player, a digital video recorder, or a digital video player, a device capable of transmitting and receiving information in a wireless environment, one of various electronic devices configuring a home network, one of various electronic devices configuring a computer network, one of various electronic devices configuring a telematics network, an RFID device, or one of various components configuring a computing system.

As an embodiment, the semiconductor memory device 100 or the memory system 1000 including the same may be mounted as a package of various types. For example, the semiconductor memory device 100 or the memory system 1000 may be packaged and mounted in a method such as a package on package (PoP), ball grid arrays (BGAs), chip scale packages (CSPs), plastic leaded chip carriers (PLCC), a plastic dual in line package (PDIP), a die in waffle pack, die in wafer form, a chip on board (COB), a ceramic dual in line package (CERDIP), a plastic metric quad flat pack (MQFP), a thin quad flat pack (TQFP), a small outline integrated circuit (SOIC), a shrink small outline package (SSOP), a thin small outline package (TSOP), a system in package (SIP), a multi-chip package (MCP), a wafer-level fabricated package (WFP), or a wafer-level processed stack package (WSP).

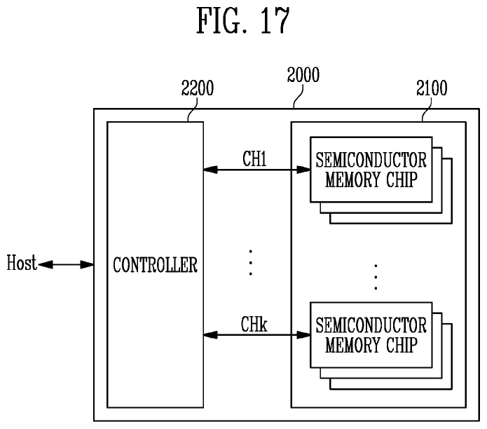

FIG. 17 is a block diagram illustrating an application example of the memory system of FIG. 1.

Referring to FIG. 17, a memory system 2000 includes a semiconductor memory device 2100 and a controller 2200. The semiconductor memory device 2100 includes a plurality of semiconductor memory chips. The plurality of semiconductor memory chips are divided into a plurality of groups.

In FIG. 17, the plurality of groups communicate with the controller 2200 through first to k-th channels CH1 to CHk, respectively. Each semiconductor memory chip is configured and operates similarly to that of the semiconductor memory device 100 described with reference to FIG. 2.

Each of the plurality of groups is configured to communicate with the controller 2200 through one common channel. The controller 2200 is configured similarly to the controller 200 described with reference to FIG. 16 and is configured to control the plurality of memory chips of the semiconductor memory device 2100 through the plurality of channels CH1 to CHk.

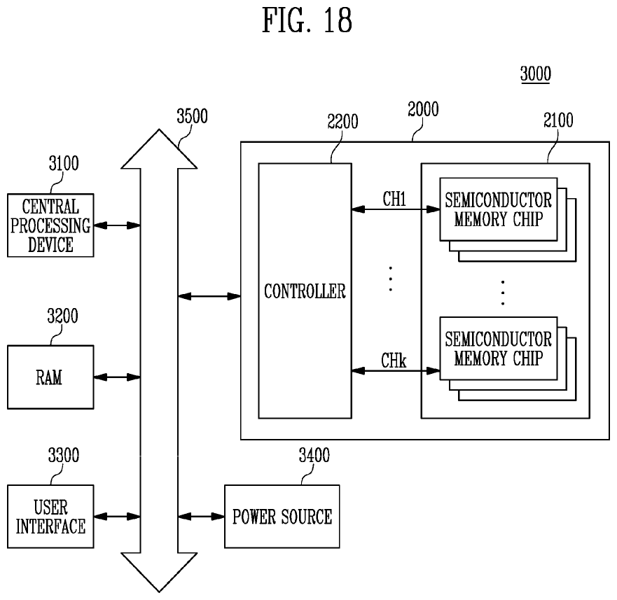

FIG. 18 is a block diagram illustrating a computing system 3000 including the memory system described with reference to FIG. 17.

The computing system 3000 includes a central processing device 3100, a random access memory (RAM) 3200, a user interface 3300, a power source 3400, a system bus 3500, and the memory system 2000.

The memory system 2000 is electrically connected to the central processing device 3100, the RAM 3200, the user interface 3300, and the power source 3400 through the system bus 3500. Data provided through the user interface 3300 or processed by the central processing device 3100 is stored in the memory system 2000.

In FIG. 18, the semiconductor memory device 2100 is connected to the system bus 3500 through the controller 2200. However, the semiconductor memory device 2100 may be configured to be directly connected to the system bus 3500. At this time, a function of the controller 2200 is performed by the central processing device 3100 and the RAM 3200.

In FIG. 18, the memory system 2000 described with reference to FIG. 17 is provided. However, the memory system 2000 may be replaced with the memory system 1000 including the controller 200 and the semiconductor memory device 100 described with reference to FIG. 16.

The embodiments of the present disclosure disclosed in the present specification and drawings are merely provided with specific examples to easily describe the technical content of the present disclosure and to help understanding of the present disclosure, and are not intended to limit the scope of the present disclosure. It is obvious to those of ordinary skill in the art that other modified examples based on the technical spirit of the present disclosure may be implemented in addition to the embodiments disclosed herein.

What is claimed is:

1. A controller that controls an operation of a semiconductor memory device including a reference storage area and a normal storage area, the controller comprising:
a power supply sensor configured to generate a power-on signal indicating that a memory system including the controller is powered-on;
a command generator configured to generate a read command for reading reference data stored in the reference storage area in response to the power-on signal and transfer the read command to the semiconductor memory device; and
a refresh count manager configured to analyze the read reference data received from the semiconductor memory device and determine whether a threshold voltage distribution of memory cells included in the reference storage area is changed,
wherein the command generator controls the semiconductor memory device to perform a refresh operation on the reference data stored in the reference storage area based on a result of the determination of the refresh count manager.

2. The controller of claim 1, wherein the refresh count manager updates a refresh count value for the reference storage area in response to the performing of the refresh operation, the refresh count value representing a number of times the refresh operation is performed on the reference data stored in the reference storage area.

3. The controller of claim 1, further comprising:
a bad block manager configured to update a number of bad blocks among a plurality of memory blocks included in the semiconductor memory device.

4. The controller of claim 2, wherein the controller controls the semiconductor memory device to program the reference data in the reference storage area in a single-level cell (SLC) program method.

5. The controller of claim 4, wherein the refresh count manager determines whether the threshold voltage distribution of the memory cells included in the reference storage area is changed, based on at least one of a number of bits of “0” and a number of bits of “1” included in the read reference data.

6. The controller of claim 5, wherein when it is determined that the threshold voltage distribution of the memory cells included in the reference storage area is changed, the command generator generates a command for erasing the reference data stored in the reference storage area and then generates a command for programming new reference data in the reference storage area.

7. The controller of claim 6, wherein the refresh count manager receives a bad block-refresh count association table stored in a system storage area of the semiconductor memory device, and updates the bad block-refresh count association table based on the updated refresh count value, in response to the performing of the refresh operation.

8. The controller of claim 5, wherein the reference data including only bits of “0” are programmed in the reference storage area, and
the refresh count manager determines that the threshold voltage distribution of the memory cells included in the reference storage area is changed when the number of bits of “1” included in the read reference data is equal to or greater than a predetermined threshold value.

9. The controller of claim 5, wherein the reference data including only bits of “1” are programmed in the reference storage area, and
the refresh count manager determines that the threshold voltage distribution of the memory cells included in the reference storage area is changed when the number of bits of “0” included in the read reference data is equal to or greater than a predetermined threshold value.

10. The controller of claim 5, wherein the reference data including a number of bits of “0” and a number of bits of “1” that are equal to each other are programmed in the reference storage area, and the refresh count manager determines that the threshold voltage distribution of the memory cells included in the reference storage area is changed when a value obtained by subtracting the number of bits of “1” included in the programmed reference data from the number of bits of “1” included in the read reference data is equal to or greater than a predetermined threshold value.

11. The controller of claim 5, wherein the reference data including a number of bits of “0” and a number of bits of “1” that are equal to each other are programmed in the reference storage area, and
the refresh count manager determines that the threshold voltage distribution of the memory cells included in the reference storage area is changed when a number of memory cells having a threshold voltage between a first read voltage and a second read voltage greater than the first read voltage is equal to or greater than a predetermined threshold value.

12. A method of operating a controller that controls an operation of a semiconductor memory device including a reference storage area and a normal storage area, the method comprising:
sensing a turn-on state of a memory system including the controller;
reading reference data stored in the reference storage area;
determining whether a threshold voltage distribution of memory cells included in the reference storage area is changed, based on the read reference data; and
performing a refresh operation on the reference data stored in the reference storage area in response to a determination that the threshold voltage distribution is changed by a degree equal to or greater than a predetermined threshold value.

13. The method of claim 12, further comprising:
updating a refresh count value for the reference storage area in response to the performing of the refresh operation, the refresh count value representing a number of times the refresh operation is performed on the reference data stored in the reference storage area.

14. The method of claim 13, further comprising:
updating a bad block-refresh count association table based on the updated refresh count value,
wherein, for each power-on sequence of the memory system, the bad block-refresh count association table includes an accumulated number of bad blocks generated in the memory system and the refresh count value, the power-on sequence representing a turn-on period of the memory system.

15. The method of claim 12, wherein performing the refresh operation comprises controlling the semiconductor memory device to program the reference data in the reference storage area in an SLC program method.

16. The method of claim 15, wherein controlling the semiconductor memory device to program the reference data in the reference storage area in the SLC program method comprises programming the reference data using a verify voltage, and
reading the reference data stored in the reference storage area comprises reading the reference data stored in the reference storage area with a read voltage lower than the verify voltage.

17. The method of claim 16, wherein determining whether the threshold voltage distribution of the memory cells included in the reference storage area is changed comprises determining whether the threshold voltage distribution of the memory cells included in the reference storage area is changed based on at least one of a number of bits of “0” and a number of bits of “1” included in the read reference data.

18. The method of claim 17, wherein the reference data including only bits of “0” are programmed in the reference storage area, and
determining whether the threshold voltage distribution of the memory cells included in the reference storage area is changed comprises determining that the threshold voltage distribution of the memory cells included in the reference storage area is changed in response to determination that the number of bits of “1” included in the read reference data is equal to or greater than a predetermined value.

19. The method of claim 17, wherein the reference data including only bits of “1” are programmed in the reference storage area, and
determining whether the threshold voltage distribution of the memory cells included in the reference storage area is changed comprises determining that the threshold voltage distribution of the memory cells included in the reference storage area is changed in response to determination that the number of bits of “0” included in the read reference data is equal to or greater than a predetermined value.

20. The method of claim 17, wherein the reference data including a number of bits of “0” and a number of bits of “1” that are equal to each other are programmed in the reference storage area, and
determining whether the threshold voltage distribution of the memory cells included in the reference storage area is changed comprises determining that the threshold voltage distribution of the memory cells included in the reference storage area is changed in response to determination that a number of memory cells having a threshold voltage between a first read voltage and a second read voltage greater than the first read voltage is equal to or greater than a predetermined value.
